(19) United States
(12) Patent Application Publication
(10) Pub. No.: US 2013/0343016 A1
(43) Pub. Date: Dec. 26, 2013

(54) ELECTRONIC DEVICE AND HOUSING THEREOF

(71) Applicants: HONG FU JIN PRECISION INDUSTRY (SHENZHEN) CO.,LT, Shenzhen (CN); HON HAI PRECISION INDUSTRY CO., LTD., New Taipei (TW)

(72) Inventor: GUO-QING ZHOU, Shenzhen (CN)

(73) Assignees: HON HAI PRECISION INDUSTRY CO., LTD., New Taipei (TW); HONG FU JIN PRECISION INDUSTRY (ShenZhen) CO., LTD., Shenzhen (CN)

(21) Appl. No.: 13/688,792

(22) Filed: Nov. 29, 2012

(30) Foreign Application Priority Data
Jun. 20, 2012 (CN) 2012102047978

(51) Int. Cl. H05K 5/02

(52) U.S. Cl. CPC H05K 5/0217
USPC 361/752; 361/679.01; 312/223.1

(57) ABSTRACT

A housing for an electronic device includes a upper housing and a lower cover. The upper housing has an open end including two opposite inwardly protruding tabs. Each protruding tab defines a through hole. The lower cover has an inner surface including four posts, each of which includes a projection protruding from a lateral surface. A slot is defined between each projection and the inner surface. The inner surface defines two through openings aligned with the projections. Each projection defines a threaded hole opposite to the corresponding through opening. Each protruding tab engages one slot, thereby enabling each protruding tab to be slidable with respect to the lower cover. When each protruding tab slides to a predetermined position, each through hole is aligned with one through opening, allowing a screw to pass through the through hole and the corresponding one through opening and to be screwed into one threaded hole.

### BACKGROUND

1. Technical Field

The present disclosure relates to an electronic device and a housing for the electronic device.

2. Description of Related Art

Many electronic devices need to pass a drop test before shipment. Housings of the electronic devices are an important aspect for the electronic devices to pass the drop test. Although some conventional housings can satisfy basic requirements, a new housing for an electronic device is still needed.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is an isometric view of one embodiment of an electronic device.

FIG. 2 is an isometric exploded view of the electronic device of FIG. 1.

FIG. 3 is a cross-sectional view of the electronic device of FIG. 1.

### DETAILED DESCRIPTION

Embodiments of the present disclosure will be described with reference to the accompanying drawings.

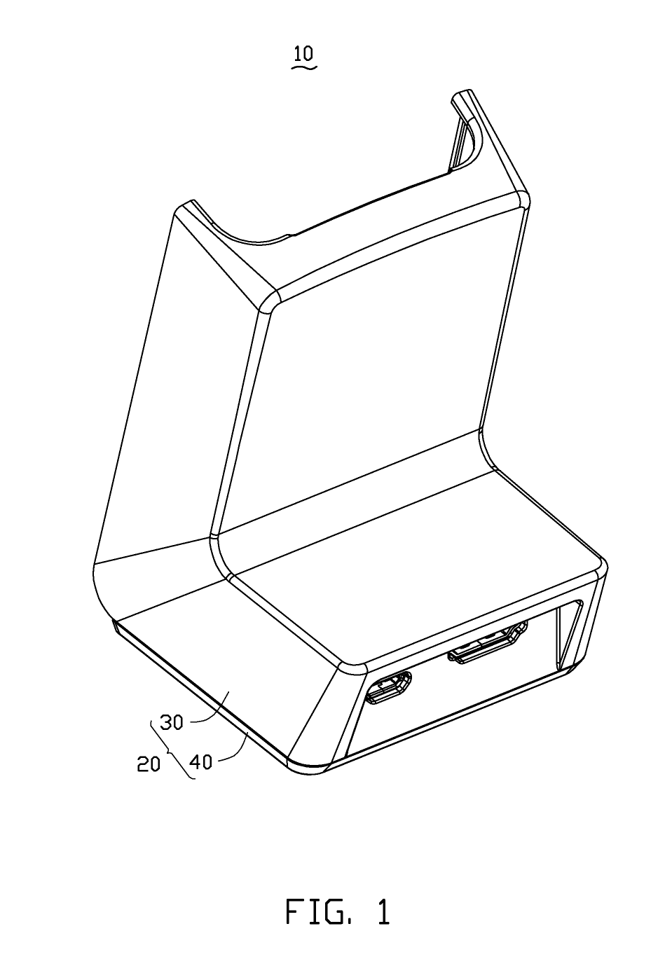

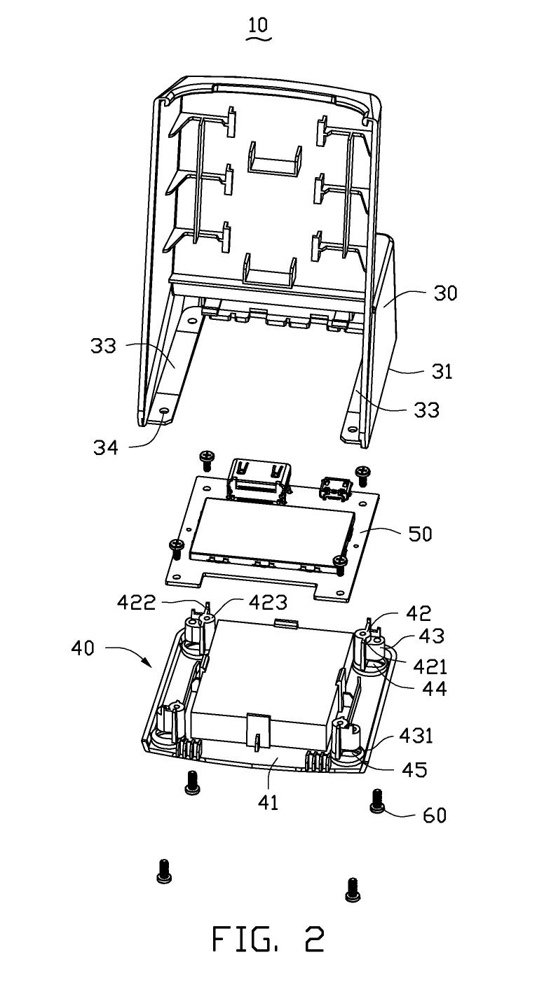

FIGS. 1 and 2 illustrate an electronic device 10 having a housing 20 that includes a hollow upper housing 30 and a lower cover 40. The upper housing 30 and the lower cover 40 cooperatively define a space to receive a circuit board 50. The upper housing 30 includes an open end 31. The open end 31 includes two opposite inwardly protruding tabs 33. Each protruding tab 33 defines two through holes 34.

The lower cover 40 is substantially planar and includes an inner surface 41. The inner surface 41 includes four posts 42 and each post 42 includes a projection 43 protruding from a lateral surface 421. In other embodiments, the number of the posts 42 can be varied according to need, for example, two or three posts 42 can be arranged on the inner surface 41. A lower end 431 of each projection 43 is located above the inner surface 41. A slot 44 is defined between the lower end 431 and the inner surface 41.

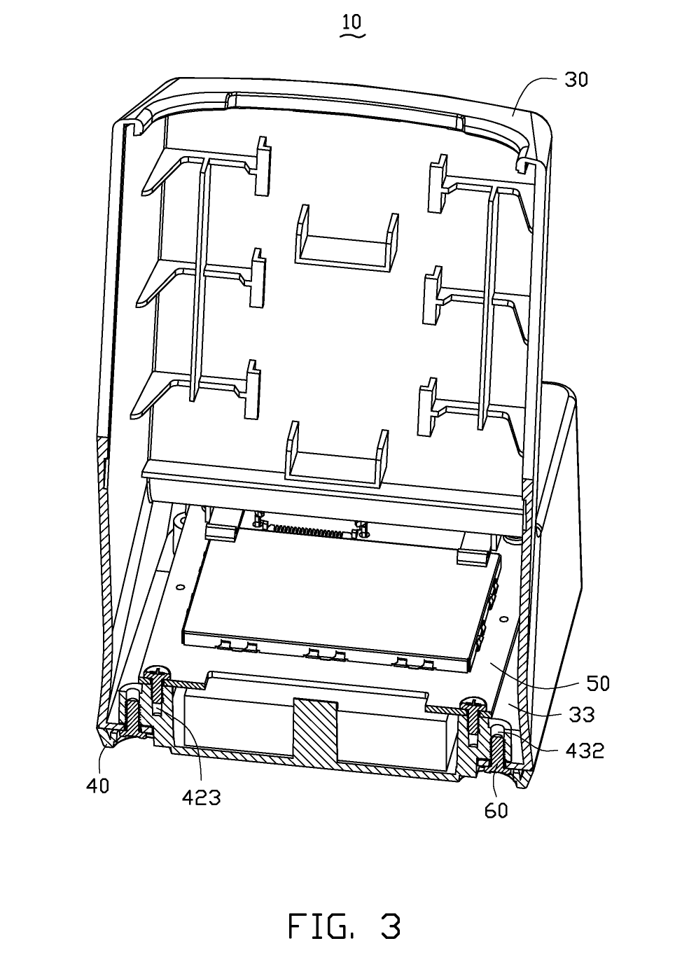

The lower cover 40 further defines one through opening 45 under the lower end 431 of each projection 43. Each projection 43 defines a threaded hole 432 (FIG. 3) in the lower end 431. The thread hole 432 is aligned with the through opening 45 under the corresponding projection 43.

In the embodiment, each protruding tab 33 can engage two slots 44, thereby enabling each protruding tab 33 to be slidable with respect to the lower cover 40. When each protruding tab 33 slides to a predetermined position, each through hole 34 is aligned with one corresponding through opening 45, allowing a screw 60 to pass through the through hole 34 and the through opening 45 and to be screwed into one threaded hole 432, thereby securing the lower cover 40 to the upper housing 30.

In one embodiment, each post 42 defines a threaded opening 423 in a top 422 thereof, thereby allowing the circuit board 50 to be secured to the top 422 by screws.

While various embodiments have been described and illustrated, the disclosure is not to be construed as being limited thereto. Various modifications can be made to the embodiments by those skilled in the art without departing from the true spirit and scope of the present disclosure as defined by the appended claims.

What is claimed is:

1. A housing for an electronic device, comprising:
a hollow upper housing comprising an open end, the open end comprising two opposite protruding tabs protruding inwardly therefrom, and each protruding tab defining a through hole; and
a lower cover comprising an inner surface, the inner surface comprising at least two posts, each of the at least two posts comprising a projection protruding from a lateral surface thereof, a slot being defined between each projection and the inner surface, the inner surface further defining two through openings respectively aligned with the projections, each projection defining a threaded hole opposite to the corresponding through opening;
wherein each protruding tab engages one of the slot, thereby enabling each protruding tab to be slidable with respect to the lower cover, when each protruding tab slides to a predetermined position, each of the through holes is aligned with one of the through openings, allowing a screw to pass through the through hole and the corresponding one through opening and to be screwed into one of the threaded holes.

2. The housing according to claim 1, wherein each of the at least two posts defines a threaded opening in a top thereof, allowing a circuit board of the electronic device to be secured to the top of the two posts by screws.

3. The housing according to claim 1, wherein the number of the at least two posts is four, and the four posts are arranged in four corners of the lower cover.

4. An electronic device comprising:
a hollow upper housing comprising an open end, the open end comprising two opposite protruding tabs protruding inwardly therefrom, and each protruding tab defining a through hole; and
a lower cover comprising an inner surface, the inner surface comprising at least two posts, each of the at least two posts comprising a projection protruding from a lateral surface thereof, a slot being defined between each projection and the inner surface, the inner surface further defining two through openings respectively aligned with the projections, each projection defining a threaded hole opposite to the corresponding through opening;
wherein each protruding tab engages one of the slot, thereby enabling each protruding tab to be slidable with respect to the lower cover, when each protruding tab slides to a predetermined position, each of the through holes is aligned with one of the through openings, allowing a screw to pass through the through hole and the corresponding one through opening and to be screwed into one of the threaded holes.

5. The electronic device according to claim 4, further comprising a circuit board, wherein each of the at least two posts defines a threaded opening in a top thereof, allowing the circuit board to be secured to the top of the two posts by screws.

6. The electronic device according to claim 4, wherein the number of the at least two posts is four, and the four posts are arranged in four corners of the lower cover.
